(19) United States
(12) Patent Application Publication
(10) Pub. No.: US 2026/0352226 A1
(43) Pub. Date: Nov. 5, 2026

(54) SERIALIZATION METHOD FOR DIGITIZED DATA STREAMS

(71) Applicant: Siemens Aktiengesellschaft, 80333 München (DE)

(72) Inventors: BERND HERRMANN, Erlangen (DE); PETER JÄHNICKE, Erlangen (DE); HARALD WIESSMANN, Erlangen (DE)

(73) Assignee: Siemens Aktiengesellschaft, 80333 München (DE)

(21) Appl. No.: 19/484,761

(22) PCT Filed: Apr. 2, 2024
(86) PCT No.: PCT/EP2024/058905

§ 371 Date: Nov. 14, 2025

(30) Foreign Application Priority Data
May 16, 2023 (EP) 23173653.9

(51) Int. Cl. H03M 3/00

(52) U.S. Cl. CPC H03M 3/458

(57) ABSTRACT

A serialization method for digitized data streams of electrical operating values of an electrical inverter includes supplying to a digital serialization unit a first digital data stream having a first clock frequency for a first electrical operating value and a further digital data stream having a further clock frequency for a further electrical operating value. A serialized digital data stream is generated with the digital serialization unit by serializing the first digital data stream and the further digital data stream. A number of the clock frequencies of the first digital data stream and of the further digital data stream is determined, and an increased clock frequency for the serialized digital data stream is generated. The Increased clock frequency is increased by the number of clock frequencies, and the serialized digital data stream containing the electrical operating values in form of digitized operating values is output with the digital serialization unit.

The invention relates to a serialization method for digitized data streams of electrical operating values of electrical converters, a digital serialization unit which is designed to carry out the serialization method, and an electrical converter which comprises the digital serialization unit.

For the operation of electrical converters, various electrical operating values are required, for example actual current values in the individual alternating voltage phases for the purpose of closed-loop current control of an inverter in a frequency converter.

The cited actual current values are often determined by measuring, in the power section of the electrical converter, a voltage at the shunt resistors that are connected in the alternating voltage phases, said voltage being proportionate to the actual current value. For the closed-loop current control of the electrical converter, the analog actual current values thus determined are then converted, usually by means of a sigma-delta converter as a sigma-delta data stream, into a digital 1-bit data stream in each case.

The sigma-delta data stream is also filtered by means of an evaluation circuit which is implemented in an ASIC (Application Specific Integrated Circuit), an FPGA (Field Programmable Gate Array) or a CPLD (Complex Programmable Logic Device), for example, and thus digitized actual current values are provided to the closed-loop current control of the electrical converter.

The filtering can be effected by means of, for example, a digital low-pass filter for reducing the data speed, for example from 10 MHz to 10 kHz. The evaluation circuit identifies an average value of the sigma-delta data stream and, following the evaluation, said value represents the analog input value of the sigma-delta converter.

The shunt resistors can usually be integrated in a technically advantageous and economical manner into power semiconductor modules of IGBTs (Insulated Gate Bipolar Transistors), MOSFETs (Metal Oxide Semiconductor Field Effect Transistors) or power diodes.

These power semiconductor modules often have half-bridge circuits, and therefore, for example for a three-phase AC side application of the power semiconductor module, three half-bridge circuits are used as a six-pulse bridge circuit (B6 bridge).

For the purpose of increasing the overall power of the electrical converter, power semiconductor modules are often connected in parallel in order to be able to avoid the use of an individual and usually cost-intensive power semiconductor module of high power.

For the parallel connection of two or more power semiconductor modules in a converter or in a plurality of converters, for example for the parallel connection of power semiconductor modules in half-bridge circuits for the purpose of generating partial phases of an alternating voltage phase, a digitized sigma-delta data stream comprising digitized partial actual current values is generated from measured analog partial actual current values for each partial phase by means of a sigma-delta converter, in order to allow further processing of the previously analog partial actual current values.

These individual digitized partial actual current values are transferred by means of the digitized sigma-delta data stream to the evaluation circuit for further processing of the partial actual current values for the purpose of closed-loop or open-loop control functions of electrical converters.

This procedure demands a particularly resource-intensive solution, in particular with regard to the transmission of the sigma-delta data streams resulting from the parallel connection of the power semiconductor modules- and therefore their respective half-bridge modules-to the evaluation circuit, it being necessary here to reserve an adequate number of inputs to the evaluation circuit for the respective sigma-delta data streams of the individual partial phases.

Depending on the number of parallel-connected power semiconductor modules, a specific solution is used in each case, generally with an associated high cost of development and implementation.

It is moreover still necessary reliably to determine, in this case measure, the total current that is measured in each of the alternating voltage phases -including AD conversion by means of the sigma-delta conversion and transmission to the evaluation circuit in the same way as the individual partial currents in the partial phases of the alternating voltage phase), resulting in further costs in respect of both the development and implementation and the need for further components such as, for example, shunt resistors for measuring the total current.

Alternatively, the voltage values that are measured at the shunt resistor and proportionate to the respective actual current value can be ascertained as analog values for each partial alternating voltage phase, and added to form an aggregated voltage value of the alternating voltage phase by means of an operational amplifier circuit. This solution is however susceptible to electrical failure and associated with reduced accuracy in relation to the actual current value that is ultimately to be determined.

The voltage values measured at the respective shunt resistors of the partial alternating voltage phases can also be converted individually into sigma-delta data streams in each case and then combined by means of an addition circuit to give an aggregated voltage value for the corresponding alternating voltage phase. This approach is however often associated with reduced accuracy in respect of the maximum possible resolution of the voltage values and consequently in relation to the resulting actual current value.

The object of the invention is to propose a serialization method, a digital serialization unit which provides the serialization method, and a converter that includes the digital serialization unit, in order to allow improved transmission of digitized data streams of electrical operating values relative to the prior art.

The object is achieved by a serialization method having the features specified in claim 1, a digital serialization unit having the features specified in claim 12, and an electrical converter having the features specified in claim 14.

In order to achieve the object, a serialization method is proposed for digitized data streams of electrical operating values, in particular of an electrical converter, with a first digital data stream for a first electrical operating value and at least one further digital data stream for at least one further electrical operating value being supplied to a digital serialization unit, with the first and the at least one further digital data stream each having a clock frequency, with a serialized digital data stream being generated by means of a serialization of the first and of the at least one further digital data stream by the digital serialization unit, with, by determining a number of clock frequencies of the first and the at least one further digital data stream, a clock frequency which is increased by the number of clock frequencies being generated for the serialized digital data stream, and with the serialized digital data stream containing the electrical operating values in the form of digitized operating values being output by the digital serialization unit.

As a consequence of the serialization of digital data streams by means of a serialized digital data stream, it is possible to achieve an efficient and economical data transmission of a plurality of digitized operating values or digitized partial operating values—each of which was generated from analog operating values or analog partial operating values, for example, it being possible for the serialized digital data stream to also comprise, in addition to the individual digitized operating values, a digitized total operating value as a sum of the digitized partial operating values—hence as a measure of a total electrical operating value, which advantageously results in reliable determination and communication of the total operating value and therefore an additional measurement of the analog total electrical operating value is not required.

By means of combining the individual digitized data streams into the serialized digital data stream, it is possible to dispense with a plurality of individual transmission paths for the respective individual digitized data streams, these comprising the digitized operating values or digitized partial operating values which are usually digitized from analog operating values or partial operating values for the closed-loop or open-loop control units of electrical devices—in particular electrical converters—specifically by transmitting the respective digitized operating values or digitized partial operating values as a summed digital total operating value by means of just one digitized transmission path via a signal line.

Advantageous embodiments of the serialization method are specified in the dependent claims.

In a first advantageous embodiment of the serialization method, the serialization of the first and of the at least one further digital data stream is performed by means of a time-shifted execution of the respective clock frequencies of the first and of the at least one further digital data stream.

The time-shifted execution of the respective clock frequencies has the advantage that an extension of the data transmission of the first and of the at least one further digital data stream during the serialization of the digitized data streams entails a reduced exposure to electrical interference in signal lines-thereby Improving the electromagnetic compatibility (EMC)—in particular at signal outputs of a serialization unit which is designed to serialize digitized data streams.

This reduced exposure to the occurrence of electrical interference in the signal lines is obtained, for example, starting from the digital serialization unit, via an evaluation unit for evaluating the serialized digital data stream for further processing of the digitized operating values, to a processor unit for the determination of switching signals and the triggering of power semiconductor switches in electrical converters by means of driver circuits.

In a further advantageous embodiment of the serialization method, the serialization of the first and of the at least one further digital data stream is performed by means of a simultaneous execution of the respective clock frequencies of the first and of the at least one further digital data stream.

This embodiment has the advantage that only one simultaneous clock with the respective clock frequencies of the first and of the at least one further digital data stream needs to be provided in order to carry out the serialization method, thereby making it simpler to implement the serialization method.

In a further advantageous embodiment of the serialization method, in addition to information relating to the electrical operating values of the first and of the at least one further electrical operating value, the serialized digital data stream comprises further information relating to an operating value sum of the first and the at least one further electrical operating value.

The serialization method is therefore particularly advantageous for the summation of partial electrical operating values as electrical operating values, said partial electrical operating values being combined by means of the operating value sum to give a total electrical operating value.

This means that, for example, partial electrical operating values from parallel-connected power semiconductor modules of one or more converters, such as partial currents in partial phases of an electrical phase, and the total operating value representing the sum of the partial operating values, such as a total current, formed from the partial currents, of the electrical phase, can be transmitted to a suitably designed closed-loop or open-loop control unit for further processing in a closed-loop or open-loop control algorithm for the converter or converters.

In a further advantageous embodiment of the serialization method, the first digital data stream and the at least one further digital data stream have an identical clock frequency as their respective clock frequency.

The selection of the identical clock frequency for the digitized data streams has the advantage that a uniform weighting of the digitized operating values is applied during the summation to give a digitized total operating value—i.e. the summation of the portions of the individual electrical operating values, as partial operating values, to give the operating value sum of the total electrical operating value.

Any deviation of the digitized operating values that represent the electrical operating values as partial operating values, and therefore in particular any distortion of these electrical operating values in the total electrical operating value, is therefore largely avoided.

In a further advantageous embodiment of the serialization method, the first and the at least one further digital data stream are generated by means of a sigma-delta conversion from analog values of the electrical operating values.

The generation of 1-bit digital data streams from analog values of electrical operating values by means of the sigma-delta conversion can advantageously provide the first and at least one further digital data stream for the processing which produces the serialized digital data stream.

The sigma-delta conversion which is used in the context of the serialization method for the purpose of analog-digital conversion of the electrical operating values into digitized operating values has the advantage that these operating values are galvanically isolated with regard to the signal flow thereof. Therefore the subsequent evaluation of the serialized digital data stream, in order to further process the electrical operating values or the digitized operating values in conjunction with the total electrical operating value or the digitized total operating value for the purpose of generating control signals and triggering drivers of the power semiconductor switches, can be effected more accurately and more quickly by applying various filters to the serialized digital data stream.

In a further advantageous embodiment of the serialization method, the electrical operating values take the form of a current value or an electrical value, in particular a voltage value, which corresponds to a current value.

The measurement of currents is an important requirement in order to operate, for example, electrical converters in drive systems or energy distribution systems by means of closed-loop or open-loop control algorithms. In this case, currents can be measured indirectly via a voltage drop at an electrical resistance through which current flows. For the purpose of the serialization method used in electrical converters, it is therefore also possible for voltages to be captured as analog electrical operating values, digitized, and transformed into the digitized serial data stream.

In a further advantageous embodiment of the serialization method, the first electrical operating value and the at least one further electrical operating value are captured as current values by a current sensing device, in particular by means of a shunt resistor or a Hall sensor or a GMR sensor.

In a further advantageous embodiment of the serialization method, the first electrical operating value, as a partial electrical operating value, corresponds to a first partial current of a first power semiconductor module of the electrical converter for a first partial phase of a first phase of an electrical network, and the at least one further electrical operating value, as a further partial electrical operating value, corresponds to a second partial current of a further power semiconductor module of the electrical converter for a second partial phase of the first phase of the electrical network, said further power semiconductor module being connected in parallel with the first power semiconductor module to a DC voltage circuit.

This embodiment is advantageously suitable for parallel connections of power semiconductor modules and operation thereof, in particular in electrical converters, where individual electrical operating values of the power semiconductor modules, such as partial currents in partial phases of the phase of the electrical network, are first transformed as analog operating values into digital operating values in each case, and the operating values thus digitized are then used to generate the serialized digital data stream, this containing the digitized total operating value as a measure of the total electrical operating value.

In a further advantageous embodiment of the serialization method, the digitized operating values from the serialized digital data stream, which correlate to the electrical operating values and/or the operating value sum thereof, are transformed by means of an evaluation unit into closed-loop control values for a processor unit.

In contrast with conventional solutions featuring the individual digitized data streams of the respective operating values, the evaluation unit receives only the serialized digitized data stream, this containing both the information relating to the individual electrical operating values and information relating to the total electrical operating value. The processor unit by means of which control signals are generated, for example for the power semiconductor modules of electrical converters, receives for example actual values of the electrical operating values and/or of the total electrical operating value transmitted from the evaluation unit.

It is possible to dispense with expansion of the evaluation unit, which is designed for example as an ASIC or FPGA and is already used in electrical converters without parallel connection of the power semiconductor modules for the further processing of digitized operating values, in terms of additional data inputs—which would supposedly be necessary for the parallel connection of the power semiconductor modules—because only one data input at the evaluation unit needs to be reserved for receiving the digitized operating values in the form of the serialized digital data stream per respective phase of the electrical network, in particular in three-phase networks.

In contrast with the use of conventional methods for summing digitized operating values, such as that of a digital addition circuit, it is thus possible by means of the inventive serialization method to avoid resolution losses of the individual operating values, and of the total operating value.

In a further advantageous embodiment of the serialization method, the closed-loop control values are transferred from the evaluation unit to the processor unit, in particular for the purpose of closed-loop control of the electrical converter,

The operating values and/or total operating values contained in the serialized digitized data stream are transferred from the evaluation unit to the processor unit in such a way that they are used as, for example, actual current values for closed-loop control of a speed/torque or generally for closed-loop current control in the electrical converter of a drive system.

For the achievement of the object, likewise proposed is a digital serialization unit which is configured to carry out the serialization method according to the invention.

The digital serialization unit for carrying out the serialization method can advantageously be configured economically in conventionally programmable modules such as an ASIC, FPGA or CPLD.

By virtue of the flexibly configurable activation and interconnection allowed by the interfaces and interconnection of the digital serialization unit and the ease of programmability when implementing the serialization method, it is conceivable, in addition to the cited measuring arrangements and application areas for capturing current and voltage, to capture further operating variables such as temperature, speed or torque, for example.

In this context, the term “electrical operating variable” is to be Interpreted in the sense that further such electrical operating variables at least affect the electrical operation of electrical components, for example parallel-connected power semiconductor modules of the electrical converter in this case.

Temperature capture for power semiconductor modules is mentioned as an example, wherein the temperature level of the power semiconductor modules can have an influence on the switching performance of these power semiconductor modules and consequently on the electrical performance of the power semiconductor modules, particularly with regard to closed-loop control considerations.

In an advantageous embodiment of the digital serialization unit, the digital serialization unit comprises an evaluation unit for evaluation of the serialized digital data stream.

For the achievement of the object, further proposed is an electrical converter comprising the digital serialization unit according to the invention, said electrical converter being provided as part of a drive system for operation of an electric motor in an electrical network or as part of an energy supply system for conversion of electrical energy in an electrical network system.

The properties, features and advantages described above in relation to this invention, and the manner in which these are achieved, become clearer and easier to understand in the context of the following description of the exemplary embodiments as explained in greater detail with reference to the figures. It is shown in:

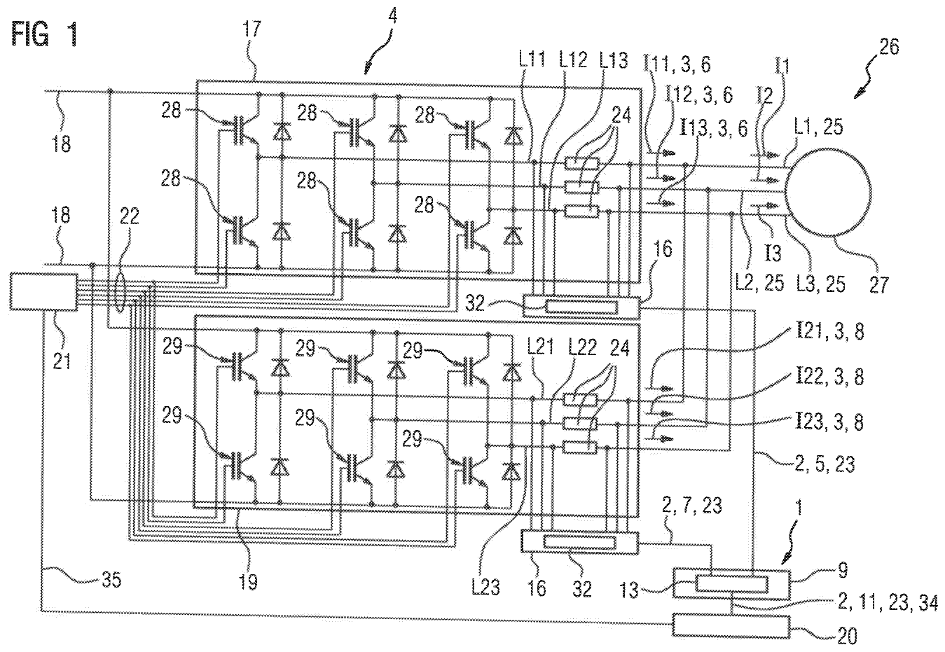

FIG. 1 a schematic illustration of a drive system with power semiconductor modules which are parallel-connected in an electrical converter, and an inventive digitized serialization unit for performing the inventive method,

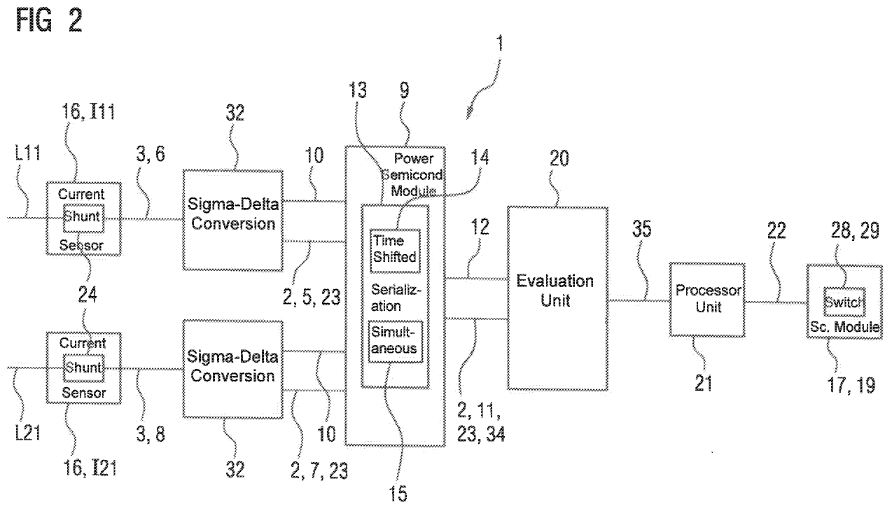

FIG. 2 a schematic block diagram of the inventive digitized serialization method according to FIG. 1,

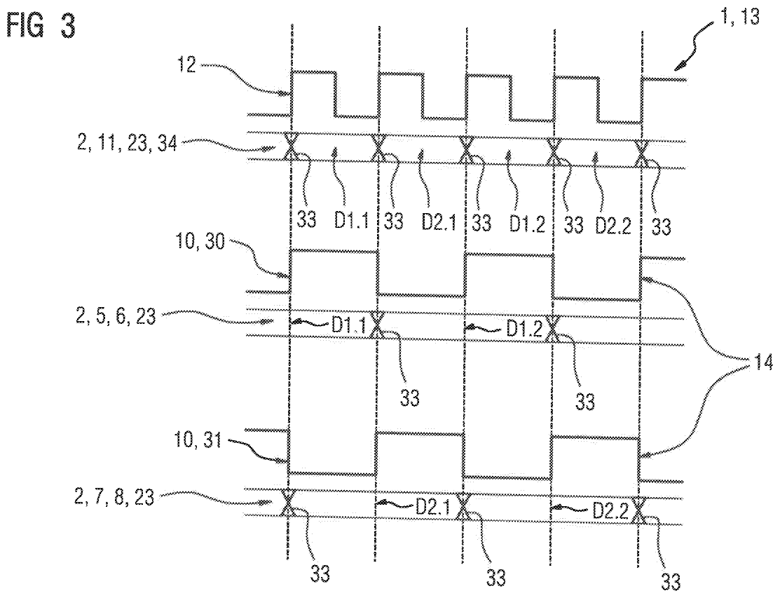

FIG. 3 a first schematic diagram of the serialization method according to FIG. 1 or FIG. 2, with a first embodiment of time sequences of clock frequencies of digital data streams, for the serialization thereof,

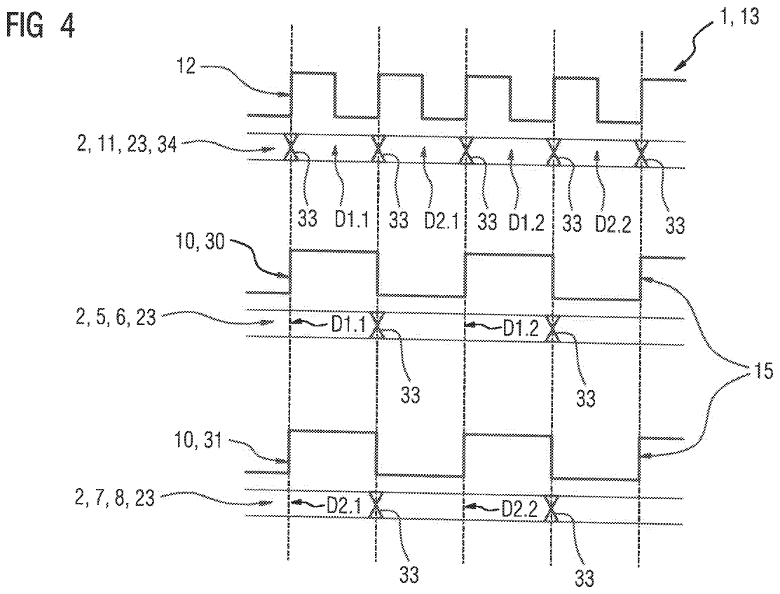

FIG. 4 a further schematic diagram of the serialization method according to FIG. 1 or FIG. 2, with reference to a further embodiment of time sequences of clock frequencies of digital data streams, for the serialization thereof.

FIG. 1 shows a schematic illustration of a drive system 26 with a first power semiconductor module 17 and a further power semiconductor module 19 which are parallel-connected in an electrical converter 4, together with an inventive digitized serialization unit 9 for performing the inventive serialization method 1.

Those aspects of the method for performing the inventive serialization method 1 which are described by FIG. 1 relate to an operating scenario of the power semiconductor modules 17,19 of the electrical converter 4.

The power semiconductor modules 17,19 are each designed as bridge modules—for example bridge modules in a six-pulse bridge circuit here—) with first power semiconductor switches 28 of the first power semiconductor module 17 and power semiconductor switches 29 of the further power semiconductor module 19.

The power semiconductor modules 17, 19 are electrically connected on the input side to a DC voltage circuit 18, which is often a DC voltage intermediate circuit of the electrical converter 4, this being designed as a frequency converter, for example.

The first power semiconductor module 17 is connected on the output side to a first partial phase L11 of a first phase L1 of an electrical network 25, a first partial phase L12 of a second phase L2 of the electrical network 25, and a first partial phase L13 of a third phase L3 of the electrical network 25.

The further power semiconductor module 19 is connected on the output side to a second partial phase L21 of the first phase L1 of the electrical network 25, a second partial phase L22 of the second phase L2 of the electrical network 25, and a second partial phase L23 of the third phase L3 of the electrical network 25.

The power semiconductor modules 17,19 in the electrical converter 4 are therefore connected in parallel between the DC voltage circuit 18 on the input side and the electrical network 25 on the output side.

The electrical network 25 is electrically connected to an electric motor 27 as a three-phase supply network via the first phase L1, the second phase L2 and the third phase L3. The electric motor 27—like the electrical converter 4—is part of the drive system 26 and can be operated by means of the electrical converter 4.

By means of the shunt resistors 24 which are used here by way of example, in the operating scenario at the first power semiconductor module 17, first electrical operating values 6 are measured in each case as electrical operating values 3 in the first partial phases L11,L12,L13 of the phases L1,L2,L3 of the electrical network 25, in the form of a first partial current I11 of the first partial phase L11 of the first phases L1 for the first current I1 in the first phase L1, in the form of a first partial current I12 of the first partial phase L12 of the second phases L2 for the second current I2 in the second phase L2, and in the form of a first partial current I13 of the first partial phase L13 of the third phases L3 for the third current I3 in the third phase L3.

These partial currents I11,I12,I13, measured as first electrical operating values 6 in the partial phases L11,L12,L13 at the first power semiconductor module 17, are captured in a current sensing device 16 as electrical operating values 3 (as analog values here) and are converted by means of a sigma-delta conversion 32 into digitized data streams 2. Each of these partial currents I11,I12,I13, measured as first electrical operating values 6, is converted into first digitized data streams 5 in each case.

Again by means of shunt resistors 24 which are used by way of example, in the operating scenario at the further power semiconductor module 19, further electrical operating values 8 are measured in each case as electrical operating values 3 in the second partial phases L21,L22,L23 of the phases L1,L2,L3 of the electrical network 25, in the form of a second partial current I21 of the second partial phase L21 of the first phases L1 for the first current I1 in the first phase L1, in the form of a second partial current I22 of the second partial phase L22 of the second phases L2 for the second current I2 in the second phase L2, and in the form of a second partial current I23 of the second partial phase L23 of the third phases L3 for the third current I3 in the third phase L3.

These partial currents I21,I22,I23, measured as further electrical operating values 6 in the partial phases L21,L22,L23 at the further power semiconductor module 19, are captured in a current sensing device 16 as electrical operating values 3—as analog values here—and are converted by means of a sigma-delta conversion 32 into digitized data streams 2. Each of these partial currents I21,I22,I23, measured as further electrical operating values 8, is converted into further digitized data streams 7 in each case.

Both the first electrical operating values 6 as first digitized data streams 5 for the first partial currents I11,I12,I13 of the first partial phases L11,L12,L13 of the phases L1,L2,L3 of the electrical network 25 and the further electrical operating values 8 as further digitized data streams 7 for the second partial currents 121,I22,I23 of the second partial phases L21,L22, L23 of the phases L1,L2,L3 of the electrical network 25 are supplied as digitized operating values 23 in each case to the digital serialization unit 9, which performs the serialization 13 from first and further digitized data streams 5,7 by means of the serialization method 1 and generates a serialized digital data stream 11.

As a digitized data stream 2, in addition to the digitized operating values 23 of the individual partial currents I11,I12,I13,I21,I22,I23 of the respective partial phases L11,L12,L13,L21,L22,L23 of the phases L1,L2,L3 of the electrical network 25, this serialized digital data stream 11 also contains operating value sums 34 of the currents I1,I2,I3 in the phases L1,L2,L3, these being composed of the individual partial currents I11,I12,I13,I21,I22,I23 for the respective currents I1,I2,I3.

For example, the first current I1 in the first phase L1 of the electrical network 25, as operating value sum 34, is therefore composed of the first electrical operating value 6 of the first digital data stream 5 in the form of the first partial current (11 of the first current I1 in the first partial phase L11 of the first phase L1 summed with the further electrical operating value 8 of the further digital data stream 7 in the form of the second partial current I21 of the first current I1 in the second partial phase L21 of the first phase L1.

This procedure takes place for all electrical operating values 3 or digitized data streams 2 thereof in the context of generating the serialized digital data stream 11 and the operating value sums 34 contained therein, based on the partial currents I11,I12,I13,I21,I22,I23 in the partial phases L11,L12,L13,L21,L22,L23 for the currents I1,L2,I3 of the phases L1,L2,L3 of the electrical network 25.

The serialized digital data stream 11 is transmitted to an evaluation unit 20 as a digitized data stream 2 containing the digitized operating values 23 and the operating value sum 34.

From the serialized digital data stream 11, this evaluation unit 20 extracts actual current values that are required for a processor unit 21 in the exemplary embodiment from the partial currents I11,I12,I13,I21,I22,I23 of the partial phases L11,L21,L13,L21,L22,L23 or the currents I1,I2,I3 of the phases L1,L2,L3 of the electrical network 25, and prepares these actual current values as closed-loop control values 35 for the processor unit 21 in such a way that, for example by means of a closed-loop current control, corresponding control signals 22 can be generated for the respective power semiconductor switches 28,29 of the power semiconductor modules 17,19 of the electrical converter 4.

A schematic block diagram of the inventive digitized serialization method 1 according to FIG. 1 is illustrated in FIG. 2.

Further to the explanations relating to the performance of the serialization method 1 as per FIG. 1, FIG. 2 shows the serialization method 1 in greater detail with reference to the exemplary examination of the first partial phase 111 of the first phase of the electrical network, and of the second partial phase L21 of the first phase of the electrical network, these being connected on the output side of the power semiconductor modules 17,19 to the corresponding power semiconductor modules 17,19 as illustrated in FIG. 1, the electrical network 25 as per FIG. 1 having further phases L2,L3 in addition to the first phase L1 and the further phases L2,L3 being formed from the further partial phases L12,L13,L21,L22 in each case.

By means of the shunt resistor 24 and the current sensing device 16 for the first partial phase L11 of the first phase of the electrical network, the first partial current I11 of the first current of the first phase is measured as an electrical operating value 3 in the first partial phase L11, said first partial current I11 representing the first electrical operating value 6.

From the first electrical operating value 6 (an analog current value here), the sigma-delta conversion 32 generates a digitized operating value 23 (a digital 1-bit current value here) as a digitized data stream 2, which is designed in the form of the first digital data stream 5 with a clock frequency 10.

By means of the shunt resistor 24 and the current sensing device 16 for the second partial phase L21 of the first phase of the electrical network, the second partial current I21 of the first current of the first phase is measured as an electrical operating value 3 in the second partial phase L21, the second partial current I21 representing the further electrical operating value 8.

From the further electrical operating value 8—an analog current value here—the sigma-delta conversion 32 generates a digitized operating value 23—a digital 1-bit current value here—as a digitized data stream 2, which is designed in the form of the further digital data stream 7 with a clock frequency 10.

The first digital data stream 5, which contains the first electrical operating value 6—the first partial current I11 of the first current of the first phase and the further digital data stream 7, which contains the further electrical operating value 8—the second partial current I21 of the first current of the first phase—are transmitted to the digital serialization unit 9, which performs the serialization 13 of both digital data streams 5,7 by means of the serialization method 1.

The serialization unit 9 generates the serialized digital data stream 11 as a digitized data stream 2 by means of a time shift 14 of the respective clock frequencies 10 of the digital data streams 5,7 or by means of a simultaneous execution 15 of the respective clock frequencies 10 of the digital data streams 5,7. The respective clock frequencies 10 of the digital data streams 5,7 are ideally identical.

The serialized digital data stream 11 has a clock frequency 12 which is increased by the number of the clock frequencies 10 of the first and of the one further digital data stream 5,7.

In addition to the first digital data stream 5, which represents the first electrical operating value 6, and the further digital data stream 7, which represents the further electrical operating value 8, the serialized digital data stream 11 also includes the operating value sum 34 of both electrical operating values 6,8.

In the example, the operating value sum 34 is therefore the first current in the first phase of the electrical network, this being formed by the sum of the first partial current I11 of the first current of the first phase and the second partial current I21 of the first current of the first phase.

From the serialized digital data stream 11 with the increased clock frequency, the evaluation unit 20 extracts the actual current values that are correspondingly required for the processor unit 21 in the exemplary embodiment from the partial current I11 of the partial phase L11 as first electrical operating value 6, from the partial current I21 of the partial phase L21 as further electrical operating value 8, and in particular the first current of the first phases of the electrical network from the operating value sum 34, this being formed by the sum of the first electrical operating value 6 and the further electrical operating value 8.

These electrical operating values 6,8 and the operating value sum 34 are prepared as closed-loop control values 35 the form of actual current values for the processor unit 21 in such a way that, for example by means of a closed-loop current control, corresponding control signals 22 can be generated for the respective power semiconductor switches 28,29 of the power semiconductor modules 17,19 of the electrical converter.

The serialization method in this case is not limited only to current values as electrical operating values, but can relate to further operating values which have an influence on the operating performance or on electrical variables of electrical devices, in particular caused here by the parallel connection of electronic modules such as the illustrated power semiconductor modules 17,19 of the electrical converter 4 In FIG. 1 and the power semiconductor modules 17,19 in FIG. 2.

The capture and further processing of such a further operating value may relate to a temperature at the power semiconductor modules 17,19, for example.

FIG. 3 shows a first schematic diagram of the serialization method 1 according to FIG. 1 or FIG. 2 with a first embodiment of time sequences in the form of a time-shifted execution 14 of clock frequencies 10,30,31 of the digital data streams 2,5,7 for the serialization 13 thereof as a serialized digital data stream 2,11.

In a first diagram part of the schematic diagram of the serialization method 1 according to FIG. 3, the first digital data stream 5 is shown as a digitized data stream 2, said first digital data stream 5 representing the first electrical operating value 6—for example the first partial current I11 in the first partial phase L11 for the first current I1 of the first phase L1 of the electrical network 25 in the exemplary embodiment as per FIG. 1 or FIG. 2—as digitized operating value 23.

The first digital data stream 5 has a first clock frequency 30 as clock frequency 10.

In a further diagram part of the schematic diagram of the serialization method 1 according to FIG. 3, the further digital data stream 7 is shown as digitized data stream 2, said further digital data stream 7 representing the further electrical operating value 8—the second partial current I21 in the second partial phase L21 for the first current I1 of the first phase L1 of the electrical network 25 in the exemplary embodiment as per FIG. 1 or FIG. 2—as digitized operating value 23.

The further digital data stream 7 has a further clock frequency 31 as clock frequency 10.

The clock frequencies 10 of the first clock frequency 30 and the further clock frequency 31 are identical in the exemplary embodiment as per FIG. 3 and form a reciprocally time-shifted execution 14, such that the first clock frequency 30 then has a high signal as a 1-bit data stream when the further clock frequency 31 has a low signal as a 1-bit data stream, or the first clock frequency 30 has a low signal when the further clock frequency 31 has a high signal.

In a further diagram part of the schematic diagram of the serialization method 1 according to FIG. 3, the serialized digital data stream 11 which is generated by means of the serialization 13 of the digital data streams 5,7 is shown as digital data stream 2, said serialized digital data stream 11 representing the operating value sum 34-the first current I1 in the first phase L1 of the electrical network 25 as a sum of the first partial current I11 in the first partial phase L11 and the second partial current I21 in the second partial phase L21 in the exemplary embodiment as per FIG. 1 or FIG. 2—as digitized operating value 23.

The serialized digital data stream 11 has an increased clock frequency 12 in comparison with the clock frequencies 10 of the first clock frequency 30 of the first digital data stream 5 and the further clock frequency 31 of the further digital data stream 7—in this case a doubled clock frequency as an increased clock frequency 12. The number of the two clock frequencies 10 of the first and of the at least one further digital data stream 5,7 here results in the doubling of the increased clock frequency 12 for the serialized digital data stream.

A data transition of the first digital data stream 5 with the first electrical operating value 6 and the further digital data stream 7 with the further electrical operating value 8 into the serialized digital data stream 11 takes place during the serialization 13 by means of data transfers D1.1,D1.2,D2.1,D2.2.

In order to achieve this, for a first data transfer D1.1, the first digital data stream 5 for the first electrical operating value 6—for example the first partial current I11 of the first partial phase L11 of the first phase L1 of the electrical network 25 for the first current I1 in the first phase L1 according to FIG. 1—is read out, usually during a high signal of the first clock frequency 30, and included in the serialized digital data stream 11, usually during the high signal of the increased clock frequency 12.

With the subsequently time-shifted execution 14 of the further clock frequency 31 relative to the first clock frequency 30, for a further data transfer D2.1, the further digital data stream 7 for the further electrical operating value 8—for example the second partial current I21 of the second partial phase L21 of the first phase L1 of the electrical network 25 for the first current I1 in the first phase L1 according to FIG. 1—is read out, usually during a high signal of the further clock frequency 31, and included in the serialized digital data stream 11, usually during the high signal of the increased clock frequency 12.

With the subsequently time-shifted execution 14 of the first clock frequency 30 relative to the further clock frequency 31, for a further data transfer D1.2, in turn the first digital data stream 5 for the first electrical operating value 6—for example in turn the first partial current I11 of the first partial phase L11 of the first phase L1 of the electrical network 25 for the first current I1 in the first phase L1 according to FIG. 1—is read out, usually during a high signal of the first clock frequency 30, and included in the serialized digital data stream 11, usually during the high signal of the increased clock frequency 12.

With the subsequently time-shifted execution 14 of the further clock frequency 31 relative to the first clock frequency 30, for a further data transfer D2.2, in turn the further digital data stream 7 for the further electrical operating value 8—for example in turn the second partial current I21 of the second partial phase L21 of the first phase L1 of the electrical network 25 for the first current I1 in the first phase L1 according to FIG. 1—is read out, usually during a high signal of the further clock frequency 31, and included in the serialized digital data stream 11, usually during the high signal of the increased clock frequency 12.

By way of example, the data transfers D1.1,D1.2,D2.1,D2.2 are sectionally provided with exclusion areas 33 where, in particular at an edge change of the clock frequencies 10 of the first clock frequency 30 of the first digital data stream 5, or of the further clock frequency 31 of the further digital data stream 7, and of the increased clock frequency 12 of the serialized digital data stream 11, unstable states can occur during the data transfers D1.1,D1.2,D2.1,D2.2 and therefore the data transfers D1.1,D1.2,D2.1,D2.2 are not carried out during the exclusion areas 33.

Using the serialization method 1 illustrated in the exemplary embodiment as per FIG. 3 in conjunction with the parallel connection of the first and the further power semiconductor module 17,19 as per FIG. 1, the capture and serialization 13 is performed analogously in relation to electrical operating values 3 of the partial currents I12,I22 in the partial phases L12,22 of the second phase L2 of the electrical network 25—and the transformation thereof into the serialized digital data stream 11 with the operating value sum 34 of the second current I2—and in relation to electrical operating values 3 of the partial currents I13,I23 in the partial phases L13,23 of the third phase L3 of the electrical network 25—and the transformation thereof into the serialized digital data stream 11 with the operating value sum 34 of the third current I3.

In a similar manner to the exemplary embodiment according to FIG. 3 in conjunction with FIG. 1, in addition to the parallel connection of the first and the further power semiconductor modules 17,19, further electrical operating values can also be captured and serialized in the serialized digital data stream 11, for example by means of an additional parallel connection of further power semiconductor modules.

FIG. 4 shows a further schematic diagram of the serialization method 1 according to FIG. 1 and FIG. 2 with reference to a simultaneous execution 15 of clock frequencies 10,30,31 of the digital data streams 2,5,7, and the serialization 13 thereof to form the serialized digital data stream 2,11.

In a first diagram part of the schematic diagram of the serialization method 1 according to FIG. 4, the first digital data stream 5 is shown as a digitized data stream 2, said first digital data stream 5 representing the first electrical operating value 6—for example the first partial current I11 in the first partial phase L11 for the first current I1 of the first phase L1 of the electrical network 25 in the exemplary embodiment as per FIG. 1 or FIG. 2—as digitized operating value 23.

The first digital data stream 5 has a first clock frequency 30 as clock frequency 10.

In a further diagram part of the schematic diagram of the serialization method 1 according to FIG. 4, the further digital data stream 7 is shown as digitized data stream 2, said further digital data stream 7 representing the further electrical operating value 8—the second partial current I21 in the second partial phase L21 for the first current I1 of the first phase L1 of the electrical network 25 in the exemplary embodiment as per FIG. 1 or FIG. 2—as digitized operating value 23.

The further digital data stream 7 has a further clock frequency 31 as clock frequency 10.

The clock frequencies 10 of the first clock frequency 30 and the further clock frequency 31 are identical in the exemplary embodiment as per FIG. 4 and together form a simultaneous execution 15, such that the first clock frequency 30 and the further clock frequency 31 have a high signal and a low signal simultaneously as a 1-bit data stream in each case.

In a further diagram part of the schematic diagram of the serialization method 1, the serialized digital data stream 11 which is generated by means of the serialization 13 of the digital data streams 5,7 is shown as digital data stream 2, said serialized digital data stream 11 representing the operating value sum 34—the first current I1 in the first phase L1 of the electrical network 25 as a sum of the first partial current I11 in the first partial phase L11 and the second partial current I21 in the second partial phase L21 in the exemplary embodiment as per FIG. 1—as digitized operating value 23.

The serialized digital data stream 11 has an increased clock frequency 12 in comparison with the clock frequencies 10 of the first clock frequency 30 of the first digital data stream 5 and the further clock frequency 31 of the further digital data stream 7-in this case a doubled clock frequency as an increased clock frequency 12. The number of the two clock frequencies 10 of the first and of the at least one further digital data stream 5,7 here results in the doubling of the increased clock frequency 12 for the serialized digital data stream.

A data transition of the first digital data stream 5 with the first electrical operating value 6 and the further digital data stream 7 with the further electrical operating value 8 takes place during the serialization 13 by means of data transfers D1.1,D1.2,D2.1,D2.2.

In order to achieve this, for a first data transfer D1.1, the first digital data stream 5 for the first electrical operating value 6—for example the first partial current I11 of the first partial phase L11 of the first phase L1 of the electrical network 25 for the first current I1 in the first phase L1 according to FIG. 1—is read out, usually during a high signal of the first clock frequency 30, and included in the serialized digital data stream 11, usually during the high signal of the increased clock frequency 12.

Using the simultaneous execution 15 of the further clock frequency 31 and the first clock frequency 30, for a further data transfer D2.1, the further digital data stream 7 with the further electrical operating value 8—for example the second partial current I21 of the second partial phase L21 of the first phase L1 of the electrical network 25 for the first current I1 in the first phase L1 according to FIG. 1—is read out, usually during a high signal of the further clock frequency 31, and included in the serialized digital data stream 11, usually during the high signal of the increased clock frequency 12 and at least one clock pulse period of the increased clock frequency 12 following inclusion of the first digital data stream 5 with the first electrical operating value 6 by means of the serialized digital data stream 11 of the previous first data transfer D1.1, from the serialized digital data stream 11 of the further data transfer D2.1.

With the subsequently simultaneous execution 15 of the first clock frequency 30 and the further clock frequency 31, for a further data transfer D 1.2, in turn the first digital data stream 5 with the first electrical operating value 6—for example in turn the first partial current I11 of the first partial phase L11 of the first phase L1 of the electrical network 25 for the first current I1 in the first phase L1 according to FIG. 1—is read out, usually during a high signal of the first clock frequency 30, and included in the serialized digital data stream 11, usually during the high signal of the increased clock frequency 12.

With the subsequently simultaneous execution 15 of the further clock frequency 31 and the further clock frequency 30, for a further data transfer D2.2, in turn the further digital data stream 7 with the further electrical operating value 8—for example in turn the second partial current I21 of the second partial phase L21 of the first phase L1 of the electrical network 25 for the first current I1 in the first phase L1 according to FIG. 1—is read out, usually during a high signal of the further clock frequency 31, and included in the serialized digital data stream 11, usually during the high signal of the increased clock frequency 12, at least one clock pulse period following the inclusion of the first digital data stream 5 with the first electrical operating value 6 by means of the serialized digital data stream 11 of the previous further data transfer D1.2, from the serialized digital data stream 11 of the further data transfer D2.2.

By way of example, the data transfers D1.1,D1.2,D2.1,D2.2 are sectionally provided with exclusion areas 33 where, in particular at an edge change of the clock frequencies 10 of the first clock frequency 30 of the first digital data stream 5, or of the further clock frequency 31 of the further digital data stream 7, and of the increased clock frequency 12 of the serialized digital data stream 11, unstable states can occur during the data transfers D1.1,D1.2,D2.1,D2.2 and therefore the data transfers D1.1,D1.2,D2.1,D2.2 are not carried out during the exclusion areas 33.

Using the serialization method 1 illustrated in the exemplary embodiment as per FIG. 4 in conjunction with the parallel connection of the first and the further power semiconductor module 17,19 as per FIG. 1, the capture and serialization 13 is performed analogously in relation to electrical operating values 3 of the partial currents I12,I22 in the partial phases L12,22 of the second phase L2 of the electrical network 25—and the transformation thereof into the serialized digital data stream 11 with the operating value sum 34 of the second current I2—and in relation to electrical operating values 3 of the partial currents I13,I23 in the partial phases L13,23 of the third phase L3 of the electrical network 25—and the transformation thereof into the serialized digital data stream 11 with the operating value sum 34 of the third current I3.

In a similar manner to the exemplary embodiment according to FIG. 4 in conjunction with FIG. 1, in addition to the parallel connection of the first and the further power semiconductor modules 17,19, further electrical operating values can also be captured and serialized in the serialized digital data stream 11, for example by means of an additional parallel connection of further power semiconductor modules.

1.-14. (canceled)

15. A serialization method for digitized data streams of electrical operating values of an electrical converter, comprising:
supplying to a digital serialization unit a first digital data stream having a first clock frequency for a first electrical operating value and at least one further digital data stream having a further clock frequency for at least one further electrical operating value;
generating with the digital serialization unit a serialized digital data stream by serializing the first digital data stream and the at least one further digital data stream;
determining a number of the clock frequencies of the first digital data stream and of the at least one further digital data stream;
generating an increased clock frequency for the serialized digital data stream, said increased clock frequency being increased by the number of clock frequencies; and
outputting with the digital serialization unit the serialized digital data stream containing the electrical operating values in a form of digitized operating values.

16. The method (of claim 15, further comprising serializing the first digital data stream and the at least one further digital data stream by time-shifted execution of the first clock frequency and the further clock frequency.

17. The method of claim 15, further comprising serializing the first digital data stream and the at least one further digital data stream by synchronized execution of the first clock frequency and the further clock frequency.

18. The method of claim 15, wherein in addition to information relating to the electrical operating values of the first operating value and of the at least one further electrical operating value, the serialized digital data stream contains further information relating to an operating value sum of the first and the at least one further electrical operating value.

19. The method of claim 15, wherein the first digital data stream and the at least one further digital data stream have identical clock frequencies.

20. The method of claim 15, further comprising generating the first digital data stream and the at least one further digital data stream from analog values of the electrical operating values by a sigma-delta conversion.

21. The method of claim 15, wherein the electrical operating values are embodied as a current value or as an electrical value that corresponds to a current value.

22. The method of claim 21, wherein the electrical value is a voltage value.

23. The method of claim 21, wherein the first electrical operating value and the at least one further electrical operating value are captured as current values by a current sensing device.

24. The method of claim 23, wherein the current sensing comprises a shunt resistor or a Hall sensor or a GMR sensor.

25. The method of claim 21, wherein the first electrical operating value is a partial electrical operating value corresponding to a first partial current of a first power semiconductor module of the electrical converter for a first partial phase of a first phase of an electrical network, and the at least one further electrical operating value is a further partial electrical operating value corresponding to a second partial current of a further power semiconductor module of the electrical converter for a second partial phase of the first phase of the electrical network, the method further comprising connecting the further power semiconductor module in parallel with the first power semiconductor module to a DC voltage circuit.

26. The method of claim 18, further comprising transforming the digitized operating values from the serialized digital data stream that correlate with the electrical operating values or the operating value sum thereof with an evaluation unit into closed-loop control values for a processor unit.

27. The method of claim 26, further comprising transferring the closed-loop control values from the evaluation unit to the processor unit for closed-loop control of the electrical converter.

28. A digital serialization unit configured to carry out the serialization method of claim 15.

29. A digital serialization unit configured to carry out the serialization method of claim 15 and comprising an evaluation unit configured to evaluate the serialized digital data stream.

30. An electrical converter, comprising a digital serialization unit configured to carry out the serialization method of in claim 15, wherein the electrical converter is configured as part of a drive system to operate an electric motor in an electrical network or as part of an energy supply system to convert electrical energy in an electrical network system.
